(19) United States
(12) Patent Application Publication
(10) Pub. No.: US 2023/0059561 A1
(43) Pub. Date: Feb. 23, 2023

(54) IDENTIFICATION OF ARCING HAZARDS IN POWER DISTRIBUTION SYSTEMS

(71) Applicant: Lawrence Livermore National Security, LLC, Livermore, CA (US)

(72) Inventors: Indrasis Chakraborty, Pittsburg, CA (US); Jhi Young Joo, Oakland, CA (US)

(21) Appl. No.: 17/819,905

(22) Filed: Aug. 15, 2022

Related U.S. Application Data
(60) Provisional application No. 63/236,161, filed on Aug. 23, 2021.

(51) Int. Cl. G01R 31/12; G01R 31/52

(52) U.S. Cl. CPC G01R 31/1227; G01R 31/52

(57) ABSTRACT

A system to enable identification of arcing hazards comprises a data storage to store a set of measurements acquired by measurement units of a power distribution system. The system further comprises at least one processor configured to identify candidate arcing events represented by the measurements by using an unsupervised machine learning process, and to train a supervised machine learning classifier for automatic real-time identification of arcing events, by using labeled training data based on the identified candidate arcing events.

This application claims the benefit of U.S. Provisional Patent application No. 63/236,161, filed on Aug. 23, 2021, which is incorporated by reference herein in its entirety.

### STATEMENT REGARDING FEDERALLY SPONSORED RESEARCH

This invention was made with Government support under Contract No. DE-AC52-07NA27344 awarded by the United States Department of Energy. The Government has certain rights in the invention.

### TECHNOLOGY FIELD

The present invention generally pertains to identification of arcing hazards in power distribution systems, and more particularly, to a system and technique for identification of arcing hazards in power distribution systems even in the context of low current amplitudes.

### BACKGROUND

The intensity and frequency of wildfires globally have increased rapidly in recent years. Wildfires caused by electric equipment of power distribution systems have become a major concern for utilities in vulnerable regions. Power distribution systems are networks of suppliers and consumers of energy. A power distribution system includes a transmission grid and a distribution grid. Suppliers of large amounts of energy (e.g., hydroelectric plants and nuclear plants) supply high voltage electrical power to the transmission grid for transmission to substations. The substations step down the high voltage electrical power of the transmission grid to lower voltage electrical power of the distribution grid. Consumers of energy typically connect to the distribution grid.

Wildfires caused by electrical equipment are generally attributable to arcing faults. An arcing fault is essentially electric current passing through an unintended medium and can be caused by, for example, deteriorating equipment such as insulators or jumper cables or vegetation encroachment onto energized equipment such as conductors and transformers. Unfortunately, high-fidelity, high-resolution sensing and measurement infrastructures are not prevalent throughout various voltage levels of a power distribution system. Even with such an infrastructure, arcing faults that manifest with low amplitudes of current are difficult to differentiate from noise in load current. As such, arcing faults typically go undetected until their adverse consequences (e.g., wildfires) are detected.

### BRIEF DESCRIPTION OF THE DRAWINGS

One or more embodiments of the present invention are illustrated by way of example and not limitation in the figures of the accompanying drawings, in which like references indicate similar elements.

FIG. 1 is a high-level block diagram of an example of an Identification of Arcing Hazards (IAH) system.

FIG. 2 is a flow diagram showing an example of an overall process that can be performed by the IAH system.

FIG. 3 is a flow diagram showing a more detailed example of a process that can be performed by the IAH system to generate training data for use by a classifier that identifies arcing events in real time.

FIG. 4 is a high-level block diagram of a computer system in which some or all of the IAH system can be implemented.

### DETAILED DESCRIPTION

Introduced here is an Identification of Arcing Hazards (IAH) system that trains a classifier that inputs measurements of voltage and current of a power distribution system and outputs a classification indicating whether the measurements represent an arcing event. In some embodiments, the IAH system includes a training component and a classification component. The training component trains the classifier, and the classification component applies the trained classifier to classify, in real-time, measurements collected from power distributions systems as to whether the measurements represent arcing events. When used in this manner, the IAH system can detect arcing faults in a power distribution system in real-time while they are still very small in magnitude (e.g., very low current), before they become large enough to cause significant damage.

The training component identifies arcing events in training data without the need for manual identification of events, and labels the events as arcing events or non-arcing events. The training component trains a classifier using a training data set of training measurements collected from one or more power distribution systems at time intervals such as 120 measurements or higher data points per second along with raw waveform data (e.g., voltage and/or current waveforms). The measurements may include variables representing different types of measurements (e.g., phasors).

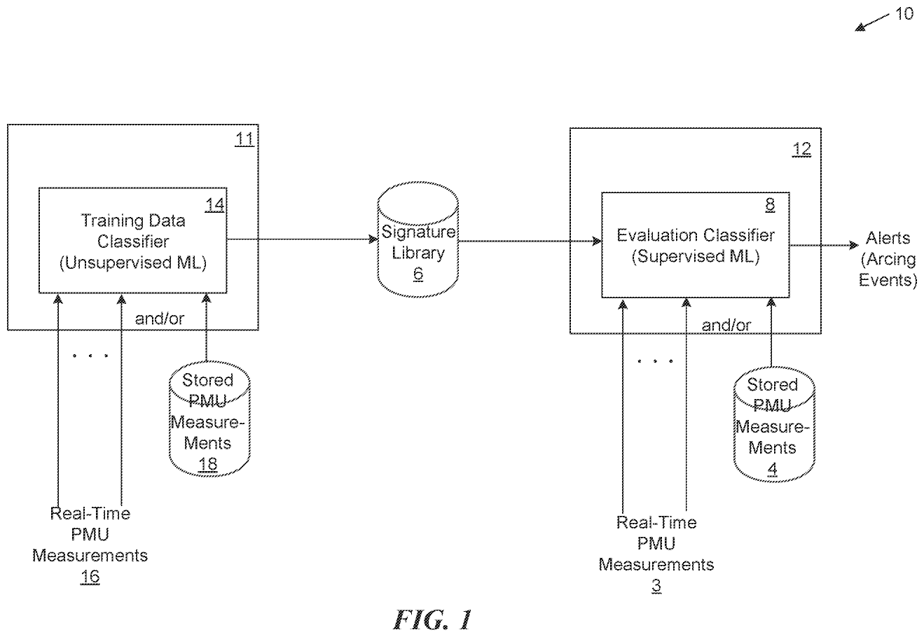

FIG. 1 illustrates an embodiment of the IAH system. In the illustrated embodiment, the IAH system 10 includes a computer system 11, which includes a training data classifier 14. The training data classifier 14 can be or include an unsupervised machine learning (ML) algorithm, which receives and inputs measurements 16 collected by, for example, various phasor measurement units (PMUs) deployed at or near one or more power distribution systems (in other embodiments, the measurements can come from sources other than PMUs). The PMU measurements 16 can be received in real time, i.e., as they are collected by the PMUs. Alternatively or additionally, the training data classifier may receive stored PMU measurements 18 that have been previously collected from one or more PMUs. Using a technique that is further described below, the training data classifier identifies candidate arcing events from the input PMU measurements 16 and/or 18. In some embodiments, a human user reviews the candidate arcing events to determine which of them represent actual arcing events, then labels all of the arcing events and/or the underlying raw waveform data as either representing or not representing arcing events, and then stores the labeled data in the signature library 6 as training data that will be used by the evaluation classifier 8. In other embodiments, the training data classifier 14 automatically determines which candidate arcing events actually represent arcing events and which do not, and labels the events and/or the underlying raw data accordingly.

In the illustrated embodiment, the system further includes a computer system 12, which includes an evaluation classifier 8. The purpose of the evaluation classifier 8 is to identify in real time (i.e., as PMU measurements 3 are collected), events that represent arcing events. To accomplish this, evaluation classifier 8 is or includes a supervised ML algorithm, which uses the training data stored in the signature library 6 to evaluate events. Computer system 12 can be, though is not necessarily, the same computer system as computer system 11. In some embodiments, the evaluation classifier 8 may additionally or alternatively evaluate stored PMU measurements 4 that have been previously collected, i.e., it may detect arcing events in an offline/batch mode.

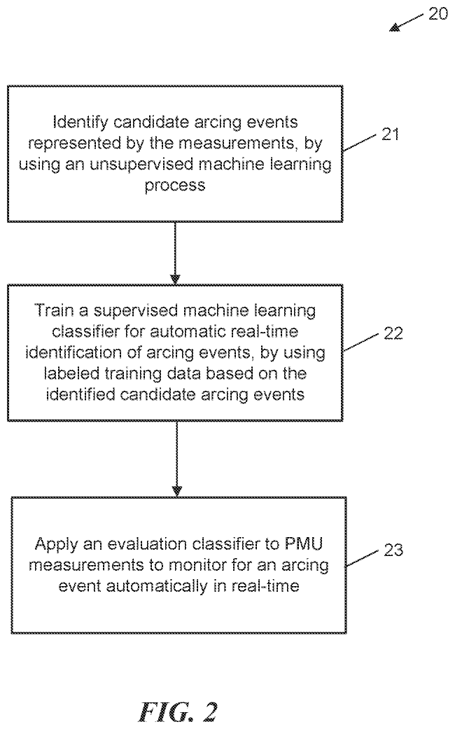

FIG. 2 illustrates an example of an overall process that may be performed by the IAH system 10 in accordance with the technique introduced here. At step 21 the process identifies candidate arcing events represented by received PMU measurements, by using an unsupervised machine learning process. At step 22 the process trains a supervised machine learning classifier for automatic real-time identification of arcing events, by using labeled training data based on the identified candidate arcing events. At step 23, the process applies an evaluation classifier to PMU measurements to monitor for an arcing event automatically in real-time.

In some embodiments the training data classifier of the IAH system reduces the dimensionality of a subset of the measurements without any “abnormal” events. The IAH system processes the subset to identify an event threshold that bounds a first-order time derivative of data points (with the reduced dimensions) in the subset. Using the threshold, the training data classifier then identifies abnormal measurements within the training data. The training data classifier may identify an abnormal event as a collection of abnormal measurements within a specified time window (e.g., 10 seconds). The training data classifier generates a similarity metric indicating similarity between pairs of the abnormal events. The training data classifier then identifies clusters of similar abnormal events (e.g., using k-means clustering). The clusters representing abnormal events that are actually arcing events are then identified. At least initially, clusters representing arcing events may be identified manually, i.e., by a human. In subsequent iterations of the process, arcing event clusters may be identified and labeled automatically, e.g., by the evaluation classifier. Once the clusters representing arcing events have been identified, training data classifier then identifies the raw waveform data corresponding to the identified arcing events and trains the classifier (e.g., neural network or support vector machine) using the raw waveform data with labels indicating whether the raw waveform data corresponds to an arcing event in the identified arcing event cluster.

The IAH system may generate or train the evaluation classifier using training data collected by phasor measurement units (PMUs). A PMU generates estimates of phasor values of the electrical quantities such as voltage, current, and frequency at typically 30 or more estimates per second, using the measurement voltages and current. The phasor values can be timestamped using the global positioning system (GPS) signal as a reference clock for time alignment. One type of PMU is a micro-phasor measurement unit (microPMU). A microPMU collects 512 samples per cycle (1 cycle is about 1/60 second) and can be configured to report up to 120 measurements per second. For example, microPMU data may be collected by a microPMU device at a 12-kilovolt substation. The microPMU dataset used by the IAH system can include variables such as three-phase voltage root mean square (rms) magnitudes and phase angles, three-phase line current rms magnitudes and phase angles, three-phase active and reactive power, and frequency.

The IAH system may detect anomalous events using a gradient-based filtering algorithm that utilizes a threshold-based algorithm. The threshold values can be different for different variables of the microPMU dataset. The IAH system may reduce the dimensions of the microPMU dataset, using linear transformation, such as principal component analysis. A two-dimensional reduced space may be sufficient to capture the variability present in the microPMU dataset. An autoencoder may alternatively be used to generate latent vectors representing the variables. Since the microPMU dataset is time-series data, the IAH system may employ a gradient-based trigger algorithm for event detection. An abnormal event is any abrupt change in magnitude of the variables (line currents, voltages, active and reactive power) present in the measurement.

In the gradient-based trigger algorithm, the threshold bound may be defined on a predefined time length of microPMU data containing no noticeable deviation of measurement variables from their nominal values. If the variation of the absolute value of the first-order time derivatives of the reduced dimensional variables are bounded by D1, then the threshold bound may be defined as D₁+ε, where ε is a user-defined positive non-zero bound tolerance added to account for the effect of measurement noise in the microPMU dataset. A gradient-based filtering algorithm detects data points in the reduced-dimensional space that cross the threshold bound. An “event” is defined as the data points surrounding the detected data point of a fixed length (e.g., 10 seconds).

The IAH system may cluster the detected events in an unsupervised manner. To do so, the IAH system may employ a similarity metric that is based on, for example, Dynamic Time Warping (DTW) for the unsupervised classification. After clustering, each cluster with arc events is identified and then used to train the evaluation classifier. The evaluation classifier may be trained using the events that are labeled as arcing or not arcing events or using raw waveform data corresponding to the events.

DTW is an algorithm for comparing two temporal sequences that do not sync up perfectly (different time length of the sequence). The DTW algorithm calculates the optimal matching between two sequences. The IAH system can employ DTW to quantify the similarity between a pair of captured events. Two captured event sequences may be represented as X=x[1], x[2], . . . , x[n] and Y=y[1], y[2], . . . , y[m], where m does not equal n where each data point of an event is represented by a vector containing the measurements. The sequences X and Y can be arranged to form a n×m grid, where each point (i, j) is the alignment between x[i] and y[j]. The objective of DTW is to find the similarity between two captured events, by formulating a “warping path,” W, that maps the data point of X and Y and subsequently minimizes the distance between them. The optimal path between a pair of (iₖ, jₖ) can be computed as

$${D}_{min} ( {i}_{k} , {j}_{k} ) = {min}_{{i}_{k - 1 ,} {j}_{k - 1}} {D}_{min} ( {i}_{k - 1 ,} {j}_{k - 1} ) + d ( {i}_{k} , {j}_{k} \vert {i}_{k - 1} , {j}_{k - 1} )$$

where d is the standard Euclidean distance. The overall path cost can be calculated by adding d(iₖ, jₖ) over k.

The IAH system can cluster events based on their similarities (e.g., as determined by using DTW) by using, for example, a k-means based unsupervised clustering algorithm. The value of the optimal k (number of clusters) can be determined by minimizing sum of squared distance between the events in each cluster and the respective cluster centroid to help ensure tightness of each determined cluster. After determining the number of clusters and the events in each cluster, each arcing event cluster containing the arcing events can then be identified (e.g., manually).

The IAH system can identify arcing events from time-series data such as raw waveform data. The IAH trains the evaluation classifier based on raw waveform data of the microPMU dataset that represent arcing events. In some embodiments, the IAH system applies filtering to separate signatures of anomalous events from the waveform data collected by the microPMUs. The filtering can include a Fast Fourier Transform (FFT) step, an inverse FFT (IFFT) step, and a noise attenuation step. In the FFT step, the IAH system applies a FFT to the waveform data to identify the present frequencies and their intensities. The IAH then subtracts the highest (in terms of magnitude) pair of conjugate frequencies, in order to capture the signature respective to the anomaly and the noise present in the waveform data. In the IFFT step, the IAH system applies an IFFT to the resulting data of the FFT step to generate a time series representation of a combination of the anomaly and the noise present in the waveform data. In the noise attenuation step, the IAH system employ a technique of wavelet shrinkage denoising, as described in Donoho, D. L. and Johnstone, J. M., “Ideal Spatial Adaptation by Wavelet Shrinkage,” Biometrika, 81(3):425-455 (1994). Such wavelet shrinkage denoising can include the following three steps: 1) wavelet transforming of the observed data; 2) thresholding the resulting wavelet coefficients; 3) inverse wavelet transforming to obtain an estimation of the signal. For the thresholding (λ), the IAH system employs the soft threshold λ=\hat{ }σ(√(2 ln N)), where α\hat{ }=M/0.6745 is the rough estimate of the signal variance, M is the median absolute deviation of wavelet coefficients, and N is the total number of data points.

The resulting signal represents the time-series representation of the anomaly present in the waveform data. These filtered time-series signature data can be used to train the evaluation classifier to identify arcing events. The trained evaluation classifier may then be used to identify arcing events from the arcing candidate event pool using the waveform data.

The IAH system may periodically retrain the evaluation classifier using measurement and raw waveform data collected over time. For example, the classifier may be retrained every day or weekly.

The portions of the raw waveforms corresponding to the events are filtered to remove noise and each portion is labeled as representing an arcing event or non-arcing event. The labeled portions are the training data for the classifier.

The evaluation classifier may be any of a variety of types of classifiers or combination of types of classifiers, including a neural networks such as a fully-connected, convolutional, recurrent, autoencoder, or restricted Boltzmann machine, a support vector machine, a Bayesian classifier, etc. When the classifier is a deep neural network, the training results in a set of weights for the activation functions of the deep neural network. A support vector machine operates by finding a hyper-surface in the space of possible inputs. The hyper-surface attempts to split the positive examples (e.g., feature vectors for photographs) from the negative examples (e.g., feature vectors for graphics) by maximizing the distance between the nearest of the positive and negative examples to the hyper-surface. This step allows for correct classification of data that is similar to but not identical to the training data. Various techniques can be used to train a support vector machine.

Adaptive boosting may be used to produce or refine the training data. Adaptive boosting is an iterative process that runs multiple tests on a collection of training data. Adaptive boosting transforms a weak learning algorithm (an algorithm that performs at a level only slightly better than chance) into a strong learning algorithm (an algorithm that displays a low error rate). The weak learning algorithm is run on different subsets of the training data. The algorithm concentrates more and more on those examples in which its predecessors tended to show mistakes. The algorithm corrects the errors made by earlier weak learners. The algorithm is adaptive because it adjusts to the error rates of its predecessors. Adaptive boosting combines rough and moderately inaccurate rules of thumb to create a high-performance algorithm. Adaptive boosting combines the results of each separately run test into a single, very accurate classifier. Adaptive boosting may use weak classifiers that are single-split trees with only two leaf nodes.

A neural network model has three major components: architecture, cost function, and search algorithm. The architecture defines the functional form relating the inputs to the outputs (in terms of network topology, unit connectivity, and activation functions). The search in weight space for a set of weights that minimizes the cost function is the training process. In one embodiment, the classification system may use a radial basis function (“RBF”) network and a standard gradient descent as the search technique.

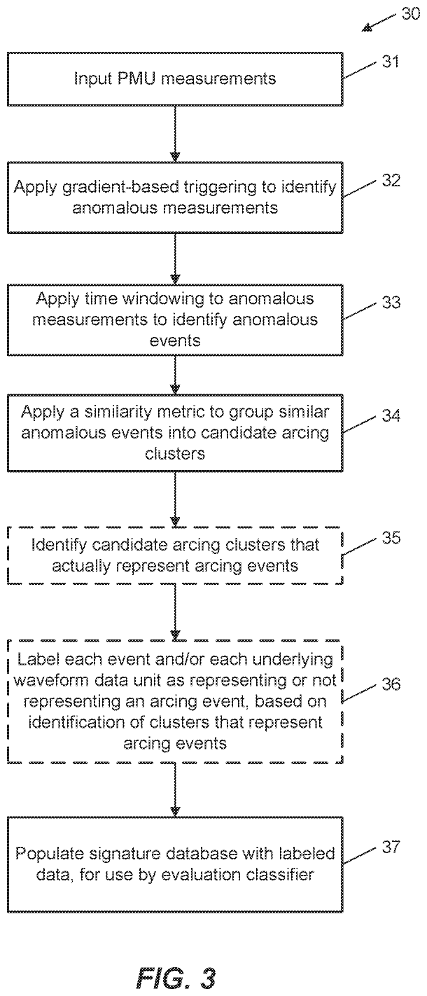

FIG. 3 illustrates a more detailed example of a process that may be performed by the IAH system, and more particularly by the training data classifier 14 (FIG. 1), to generate training data for training the evaluation classifier 8, according to one embodiment. At step 31 the process inputs PMU measurements collected by one or more PMUs. At step 32 the process applies a gradient-based triggering technique to identify anomalous measurements. At step 33 the process applies a time window to the anomalous measurements to group the anomalous measurements into events, i.e., “anomalous events.” At step 34 the process applies a similarity metric to group the anomalous events into clusters of similar anomalous events, called “candidate arcing clusters.” Next, at step 35 the process may automatically identify the candidate arcing clusters that actually represent arcing events, and at step 36 the process labels each event and/or each underlying unit of waveform data as representing or not representing an arcing event (e.g., “yes” or “no”), based on the result of step 35. In some embodiments, the process determines which events represent arcing events in step 35 by assigning a probability score to each event and applying a threshold to the probability score. In such embodiments, the events may also be labeled with their assigned probability scores in step 36, or events may be labeled with the probability score without a “yes/no” decision.

Alternatively, a human user may perform steps 35 and 36, or a human user might confirm and correct the accuracy of the results of steps 35 and 36 as performed by a machine. At step 37 the process populates the signature database 6 with the labeled data, for use by the evaluation classifier 8.

At least some aspects of the IAH system may be implemented in the form of computer-executable instructions, such as program modules and components, executed by one or more computers, processors, or other devices. Generally, program modules or components include routines, programs, objects, data structures, and so on that perform particular tasks or implement particular data types. Typically, the functionality of the program modules may be combined or distributed as desired in various embodiments. Additionally or alternatively, at least some aspects of the IAH system may be implemented in hardware using, for example, an application specific integrated circuit (ASIC) or field programmable gate array (“FPGA”).

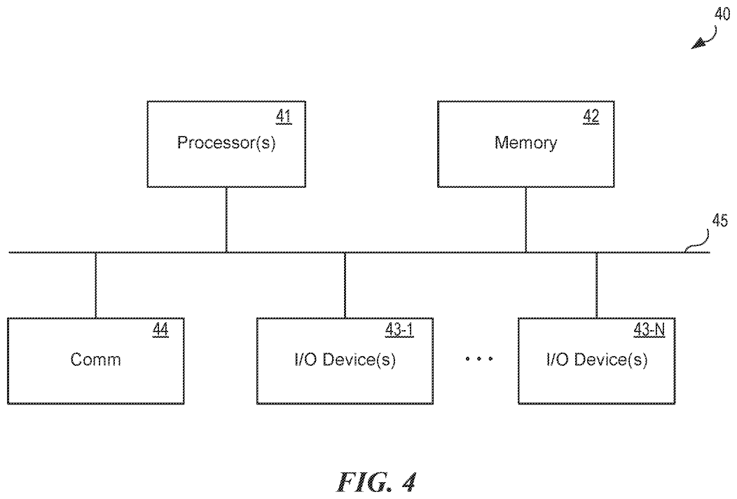

FIG. 4 is a high-level block diagram of a computer system in which at least a portion of the IAH system can be implemented. The computer system 40 in FIG. 4 may represent computer system 11 and/or computer system 12 in FIG. 1. The computer system 40 includes one or more processors 41, one or more memories 42, one or more input/output (I/O) devices 43-1 through 43-N, and one or more communication interfaces 44, all connected to each other through an interconnect 45. The processors 41 control the overall operation of the computer system 100, including controlling its constituent components. The processors 41 may be or include one or more conventional microprocessors, programmable logic devices (PLDs), field programmable gate arrays (FPGAs), application-specific integrated circuits (ASICs), etc. The one or more memories 42 stores data and executable instructions (e.g., software and/or firmware), which may include software and/or firmware for performing the techniques introduced above. The one or more memories 42 may be or include any of various forms of random access memory (RAM), read-only memory (ROM), volatile memory, nonvolatile memory, or any combination thereof. For example, the one or more memories 42 may be or include dynamic RAM (DRAM), static RAM (SDRAM), flash memory, one or more disk-based hard drives, etc. The I/O devices 43 provide access to the computer system 40 by human user, and may be or include, for example, a display monitor, audio speaker, keyboard, touch screen, mouse, microphone, trackball, etc. The communications interface 104 enables the computer system 40 to communicate with one or more external devices (e.g., an AM fabrication machine and/or one or more remote computers) via a network connection and/or point-to-point connection. The communications interface 104 may be or include, for example, a Wi-Fi adapter, Bluetooth adapter, Ethernet adapter, Universal Serial Bus (USB) adapter, or the like. The interconnect 45 may be or include, for example, one or more buses, bridges or adapters, such as a system bus, peripheral component interconnect (PCI) bus, PCI extended (PCI-X) bus, USB, or the like.

Unless contrary to physical possibility, it is envisioned that (i) the methods/steps described herein may be performed in any sequence and/or in any combination, and that (ii) the components of respective embodiments may be combined in any manner.

The machine-implemented operations described above can be implemented by programmable circuitry programmed/configured by software and/or firmware, or entirely by special-purpose circuitry, or by a combination of such forms. Such special-purpose circuitry (if any) can be in the form of, for example, one or more application-specific integrated circuits (ASICs), programmable logic devices (PLDs), field-programmable gate arrays (FPGAs), system-on-a-chip systems (SOCs), etc.

Software or firmware to implement the techniques introduced here may be stored on a machine-readable storage medium and may be executed by one or more general-purpose or special-purpose programmable microprocessors. A “machine-readable medium”, as the term is used herein, includes any mechanism that can store information in a form accessible by a machine (a machine may be, for example, a computer, network device, cellular phone, personal digital assistant (PDA), manufacturing tool, any device with one or more processors, etc.). For example, a machine-accessible medium includes recordable/non-recordable media (e.g., read-only memory (ROM); random access memory (RAM); magnetic disk storage media; optical storage media; flash memory devices; etc.), etc.

Any or all of the features and functions described above can be combined with each other, except to the extent it may be otherwise stated above or to the extent that any such embodiments may be incompatible by virtue of their function or structure, as will be apparent to persons of ordinary skill in the art. Unless contrary to physical possibility, it is envisioned that (i) the methods/steps described herein may be performed in any sequence and/or in any combination, and that (ii) the components of respective embodiments may be combined in any manner.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed is:

1. A system comprising:
a data storage to store a set of measurements acquired by measurement units of a power distribution system; and
at least one processor configured to:
identify candidate arcing events represented by the measurements, by using an unsupervised machine learning process; and
train a supervised machine learning classifier for real-time identification of arcing events, by using labeled training data corresponding to the identified candidate arcing events.

2. The system of claim 1, wherein the at least one processor is further configured to apply the classifier to a second set of measurements to identify an arcing event in real-time.

3. The system of claim 1, wherein each of the candidate arcing events corresponds to a plurality of data points for a time window, for at least one measurement.

4. The system of claim 1, wherein the unsupervised machine learning process comprises a k-means algorithm.

5. The system of claim 1, wherein identifying candidate arcing events represented by the measurements comprises:
identifying a threshold that bounds a first-order time derivative of data points in the set of measurements;
identifying, using the threshold, abnormal events within the set of measurements; and
generating a similarity metric indicative of similarity between pairs of the abnormal events.

6. The system of claim 5, wherein the similarity metric comprises a dynamic time warping (DTW) based similarity metric.

7. The system of claim 6, wherein the at least one processor is further configured to identify clusters of similar abnormal events, based on the similarity metric.

8. The system of claim 7, wherein identifying the candidate arcing events comprises identifying a candidate arcing event from among the clusters of similar abnormal events.

9. The system of claim 7, wherein identifying clusters of similar abnormal events comprises using k-means clustering.

10. The system of claim 1, wherein the at least one processor is further configured to label individual ones of the candidate arcing events as either representing or not representing an arcing event, based on a result of identifying the candidate arcing events, for use in training the classifier.

11. The system of claim 10, wherein the at least one processor is further configured to label individual ones of the candidate arcing events each with a probability that the candidate arcing event represents an arcing event.

12. The system of claim 1, wherein the at least one processor is further configured to label each of a plurality of units of raw data corresponding to the measurements as either representing or not representing an arcing event, based on a result of identifying the candidate arcing events, for use in training the classifier.

13. The system of claim 12, wherein the at least one processor is further configured to label each of the plurality of units of raw data with a probability that the unit of raw data represents an arcing event.

14. A method comprising:
accessing, by a computer system, a set of measurements taken by phasor measurement units of a power distribution system;
identifying, by the computer system, candidate arcing events represented by the measurements, by using an unsupervised machine learning process;
accessing a plurality of units of labeled data, each of the units of labeled data being labeled as either representing or not representing an arcing event, the plurality of units of labeled data including at least one of:
labeled anomalous events selected from among the candidate arcing events, or
labeled raw waveform data corresponding to anomalous events selected from among the candidate arcing events; and
training, by using the plurality of units of labeled data, a classifier for use in automatic real-time identification of arcing events in the power distribution system.

15. The method of claim 14, wherein each of the events corresponds to a plurality of data points for a time window, for at least one measurement.

16. The method of claim 14, further comprising:
applying the classifier to a second set of measurements to identify an arcing event automatically in real-time.

17. The method of claim 14, wherein the unsupervised machine learning process comprises a k-means algorithm.

18. The method of claim 14, wherein training the classifier comprises using a supervised machine learning process to train the classifier.

19. The method of claim 14, wherein identifying the candidate arcing events represented by the measurements comprises:
using a gradient-based triggering criterion to identify abnormal events within the set of measurements; and
generating a similarity metric indicative of similarity between pairs of the abnormal events.

20. The method of claim 19, wherein the similarity metric comprises a dynamic time warping (DTW) based similarity metric.

21. The method of claim 20, further comprising:
identifying clusters of similar abnormal events, based on the similarity metric.

22. The method of claim 21, wherein identifying the candidate arcing events comprises identifying a candidate arcing event from among the clusters of similar abnormal events.

23. The method of claim 22, wherein identifying clusters of similar abnormal events comprises using k-means clustering.

24. The method of claim 14, further comprising:
labeling each of a plurality of units of raw data corresponding to the measurements with a probability that the unit of raw data represents an arcing event, based on a result of identifying the candidate arcing events, for use in training the classifier.

25. The method of claim 14, further comprising:
labeling individual ones of the candidate arcing events with a probability that the candidate arcing event represents an arcing event, based on a result of identifying the candidate arcing events, for use in training the classifier.

26. A non-transitory machine-readable storage medium storing instructions, execution of which in a processing system causes the processing system to perform operations comprising:
accessing a set of measurements acquired by measurement units of a power distribution system;
identifying candidate arcing events represented by the measurements, by
identifying a threshold that bounds a first-order time derivative of data points in the set of measurements,
identifying, using the threshold, abnormal events within the set of measurements,
generating a similarity metric indicative of similarity between pairs of the abnormal events, and
identifying clusters of similar abnormal events, based on the similarity metric; and
training a supervised machine learning classifier for automatic real-time identification of arcing events, by using labeled training data based on the identified candidate arcing events.

27. The non-transitory machine-readable storage medium of claim 26, wherein said operations further comprise:
applying the classifier to a second set of measurements to identify an arcing event automatically in real-time.

28. The non-transitory machine-readable storage medium of claim 26, wherein each of the candidate arcing events corresponds to a plurality of data points for a time window, for at least one measurement.

29. The non-transitory machine-readable storage medium of claim 26, wherein identifying clusters of similar abnormal events comprises using k-means clustering.

30. The non-transitory machine-readable storage medium of claim 29, wherein the similarity metric comprises a dynamic time warping (DTW) based similarity metric.

31. The non-transitory machine-readable storage medium of claim 26, wherein said operations further comprise at least one of:
labeling individual ones of the candidate arcing events as either representing or not representing an arcing event, based on a result of identifying the candidate arcing events, for use in training the classifier; or
labeling each of a plurality of units of raw data corresponding to the measurements as either representing or not representing an arcing event, based on a result of identifying the candidate arcing events, for use in training the classifier.
